(19) United States
(12) Patent Application Publication
(10) Pub. No.: US 2016/0362588 A1
(43) Pub. Date: Dec. 15, 2016

(54) ADHESIVE COMPOSITION AND DISPLAY DEVICE

(71) Applicant: SAMSUNG DISPLAY CO., LTD., Yongin-si (KR)

(72) Inventors: Sangeun Moon, Suwon-si (KR); Kyoungsub So, Cheonan-si (KR); Hyeondeuk Hwang, Cheonan-si (KR)

(21) Appl. No.: 15/016,085

(22) Filed: Feb. 4, 2016

(30) Foreign Application Priority Data
Jun. 12, 2015 (KR) 10-2015-0083380

(51) Int. Cl. C09J 143/04; H01L 51/56; G02F 1/1333; H01L 51/52; C09J 133/06; C09J 133/02

(52) U.S. Cl. CPC C09J 143/04; C09J 133/06; C09J 133/02; G02F 1/1333; H01L 51/5246; H01L 51/56; G02F 2202/28; H01L 27/3258

(57) ABSTRACT

An adhesive composition includes: a monomer in an amount of about 25 wt % to about 50 wt %; an oligomer in an amount of about 25 wt % to about 40 wt %; a binder resin in an amount of about 10 wt % to about 40 wt %; and a photopolymerization initiator in an amount of about 1 wt % to about 10 wt % with respect to the total weight of the adhesive composition. The monomer may include acrylic acid and isobornyl acrylate, the oligomer may include silicone acrylate, and the photopolymerization initiator may include a first photoinitiator having a photosensitive wavelength of about 210 nm to about 290 nm and a second photoinitiator having a photosensitive wavelength of about 300 nm to about 390 nm.

### CROSS-REFERENCE TO RELATED APPLICATION

This application claims priority to and the benefit of Korean Patent Application No. 10-2015-0083380, filed on Jun. 12, 2015, in the Korean Intellectual Property Office, the entire content of which is incorporated herein by reference.

### BACKGROUND

1. Field

One or more aspects of example embodiments of the present disclosure relate to an adhesive composition and a display device manufactured using the adhesive composition.

2. Description of the Related Art

Display devices may be classified into liquid crystal display (“LCD”) devices, organic light emitting diode (“OLED”) display devices, plasma display panel (“PDP”) devices, electrophoretic display (“EPD”) devices, and the like, based on the light emitting scheme used therein.

In general, a display device may include a display panel configured to display an image and a window protecting the display panel, wherein the display panel and the window are attached to each other via an adhesive layer. However, for the display device to have a slimmer structure, the adhesive layer coating should be thinner. Accordingly, it is necessary that the adhesive layer between the display panel and the window exhibit strong adhesive properties.

Accordingly, research is being conducted on adhesive layers capable of stably attaching the display panel and the window to each other, and on adhesive compositions for forming the adhesive layers.

It is to be understood that this section is intended to provide useful background for understanding the technology related to the present disclosure. As such, the background section may include ideas, concepts or recognitions that were not part of what was known or appreciated by those skilled in the art prior to the effective filing date of the subject matter disclosed herein.

### SUMMARY

Aspects of one or more embodiments of the present disclosure are directed to an adhesive composition forming an adhesive layer that may stably attach a display panel and a window to each other.

Further, aspects of one or more embodiments of the present disclosure are directed to a method of manufacturing a display device using the adhesive composition.

According to one or more embodiments of the present disclosure, an adhesive composition includes: a monomer in an amount of about 25 wt % to about 50 wt %; an oligomer in an amount of about 25 wt % to about 40 wt %; a binder resin in an amount of about 10 wt % to about 40 wt %; and a photopolymerization initiator in an amount of about 1 wt % to about 10 wt % with respect to the total weight of the adhesive composition. The monomer may include acrylic acid and isobornyl acrylate, the oligomer may comprise silicone acrylate, and the photopolymerization initiator may comprise a first photoinitiator having a photosensitive wavelength of about 210 nm to about 290 nm and a second photoinitiator having a photosensitive wavelength of about 300 nm to about 390 nm.

The acrylic acid may be included in an amount of about 5 wt % to about 10 wt % with respect to the total weight of the adhesive composition.

The isobornyl acrylate may be included in an amount of about 5 wt % to about 10 wt % with respect to the total weight of the adhesive composition.

The silicone acrylate may be included in an amount of about 0.5 wt % to about 10 wt % with respect to the total weight of the adhesive composition.

The silicone acrylate may be represented by the following Chemical Formula 3:

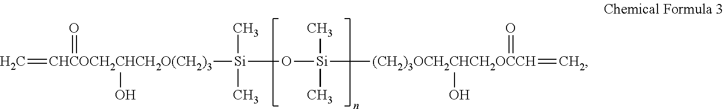

wherein n may be an integer selected from 5 to 50.

The first photoinitiator may include at least one compound selected from the chemical compounds represented by the following Chemical Formulas 4 and 5:

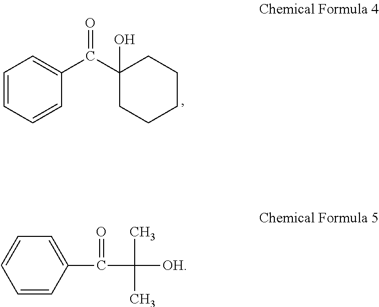

The second photoinitiator may include at least one compound selected from the chemical compounds represented by the following Chemical Formulas 8 and 9:

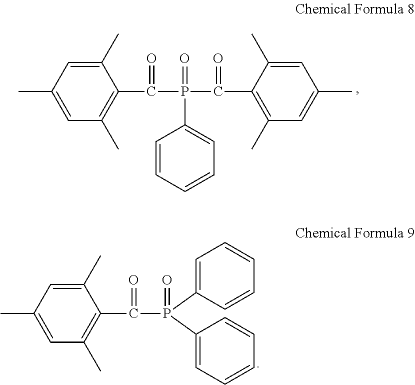

The monomer may further include at least one compound selected from lauryl acrylate, 2-ethoxyethyl acrylate, and 2-hydroxypropyl acrylate.

The oligomer may further include at least one compound selected from urethane acrylate and polyester acrylate, each having a weight-average molecular weight (Mw) of about 5,000 to about 50,000.

According to one or more embodiments of the present disclosure, a method of manufacturing a display device includes: coating an adhesive composition on a display surface of a display panel; performing a first curing on the adhesive composition using a first light source; positioning a window on the first-cured adhesive composition; and performing a second curing on the first-cured adhesive composition by irradiating the window using a second light source. The adhesive composition may include: a monomer in an amount of about 25 wt % to about 50 wt %; an oligomer in an amount of about 25 wt % to about 40 wt %; a binder resin in an amount of about 10 wt % to about 40 wt %; and a photopolymerization initiator in an amount of about 1 wt % to about 10 wt % with respect to the total weight of the adhesive composition. The monomer may include acrylic acid and isobornyl acrylate, the oligomer may include silicone acrylate, the photopolymerization initiator may include a first photoinitiator having a photosensitive wavelength of about 210 nm to about 290 nm and a second photoinitiator having a photosensitive wavelength of about 300 nm to about 390 nm, and the second light source may emit light having a wavelength longer than the wavelength of the first light source.

The acrylic acid may be included in an amount of about 5 wt % to about 10 wt % with respect to the total weight of the adhesive composition.

The isobornyl acrylate may be included in an amount of about 5 wt % to about 10 wt % with respect to the total weight of the adhesive composition.

The silicone acrylate may be included in an amount of about 0.5 wt % to about 10 wt % with respect to the total weight of the adhesive composition.

The first light source may emit light having a center wavelength of about 365 nm to about 385 nm.

The second light source may be a metal halide lamp.

The display panel may be selected from a liquid crystal display panel and an organic light emitting diode display panel.

According to one or more embodiments of the present disclosure, a display device includes: a display panel; an adhesive layer on the display panel; and a window on the adhesive layer. The adhesive layer may include a monomer, an oligomer, a binder resin, and a photopolymerization initiator, the monomer may include acrylic acid and isobornyl acrylate, the oligomer may comprise silicone acrylate, and the photopolymerization initiator may include a first photoinitiator having photosensitive wavelength of about 210 nm to about 290 nm and a second photoinitiator having a photosensitive wavelength of about 300 nm to about 390 nm.

The adhesive layer may have: an elasticity of about 2.0×10⁵ Pa to about 4.0×10⁵ Pa; an elongation index of about 200% to about 300%; and a glass transition temperature of about 15° C. to about 25° C.

The display panel may be one of a liquid crystal display panel and an organic light emitting diode display panel.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure will be more clearly understood from the following detailed description taken in conjunction with the accompanying drawings, in which:

FIG. 1 is a schematic view illustrating hydrogen bonding between acrylic acid and glass;

FIG. 2 is a schematic view illustrating wettability;

FIG. 3 is a cross-sectional view illustrating a display device according to a second example embodiment;

FIG. 4 is a plan view illustrating portion “I” of FIG. 3;

FIG. 5 is a cross-sectional view taken along line II-II′ of FIG. 4;

FIG. 6 is a cross-sectional view illustrating a display device according to a third example embodiment;

FIGS. 7A-7D are process diagrams illustrating adherence of a display panel 110 to a window 130;

FIG. 8 is a graph illustrating the relationship between heat flow and curing time of adhesive composition samples;

FIG. 9 is a graph illustrating the results of tensile strength tests on adhesive layers; and

FIG. 10 is a graph illustrating the relationships between the storage modulus G′, loss tangent “tan δ”, and temperature of adhesive layer samples.

### DETAILED DESCRIPTION

Hereinafter, embodiments of the present disclosure will now be described in more detail with reference to the accompanying drawings. However, the disclosure may be embodied in many different forms and should not be construed as being limited to the embodiments set forth herein. Rather, these embodiments are provided so that this disclosure will be thorough and complete, and will fully convey the scope of the disclosure to those skilled in the art.

All terminologies used herein are merely used to describe embodiments of the inventive concept and may be modified according to the relevant art and the intention of an applicant. Therefore, the terms used herein should be interpreted as having a meaning that is consistent with their meanings in the context of the present disclosure, and is not intended to limit the disclosure.

In the drawings, certain elements or shapes may be simplified or exaggerated to better illustrate the present disclosure, and other elements present in an actual product may be omitted. Thus, the drawings are intended to facilitate understanding of the present disclosure. Like reference numerals refer to like elements throughout the specification.

In addition, when a layer or element is referred to as being “on” another layer or element, the layer or element may be directly on the other layer or element, or one or more intervening layers or elements may be interposed therebetween.

A first example embodiment of the present disclosure provides an adhesive composition. The adhesive composition according to the first example embodiment may have photopolymerization properties.

The adhesive composition according to the first example embodiment includes: a monomer in an amount of about 25 wt % to about 50 wt %; an oligomer in an amount of about 25 wt % to about 40 wt %; a binder resin in an amount of about 10 wt % to about 40 wt %; and a photopolymerization initiator in an amount of about 1 wt % to about 10 wt % with respect to the total weight of the adhesive composition. Herein, the monomer may include acrylic acid and isobornyl acrylate, the oligomer may include silicone acrylate, and the photopolymerization initiator may include a first photoinitiator having a photosensitive wavelength of about 210 nm to about 290 nm and a second photoinitiator having a photosensitive wavelength of about 300 nm to about 390 nm.

The acrylic acid may be represented by the following Chemical Formula 1:

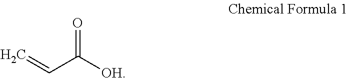

The acrylic acid has an O—H group, and the binding force between the window formed of glass and the adhesive composition may be enhanced by hydrogen bonding.

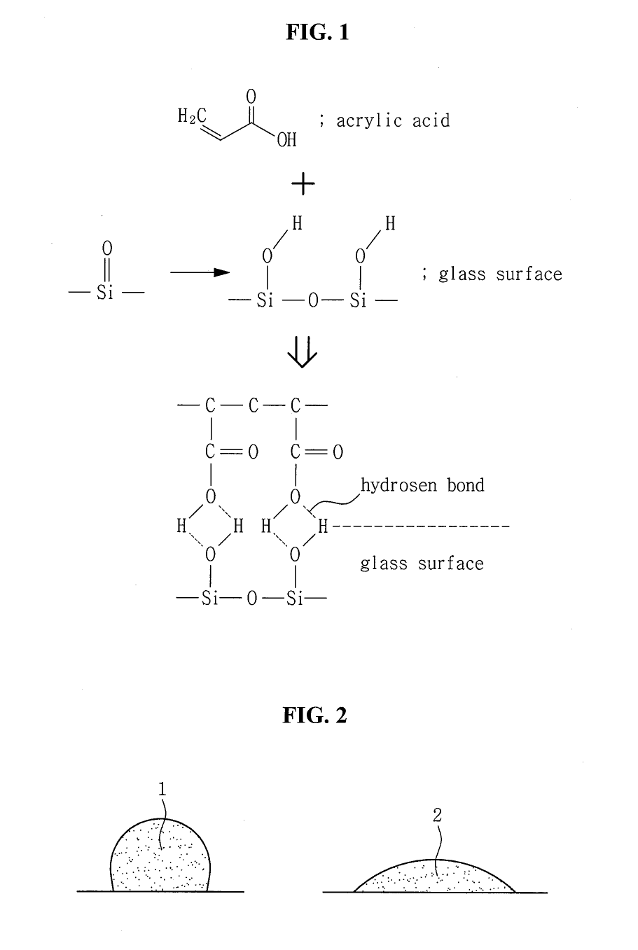

FIG. 1 is a schematic view illustrating hydrogen bonding between acrylic acid and glass.

In reference to FIG. 1, the glass contains a Si═O group, and the surface of the glass has Si—O—H groups formed by the reaction between the Si═O group and hydrogen atoms. The Si—O—H group on the surface of the glass forms hydrogen bonds with the O—H group of the acrylic acid. Accordingly, the glass window and the adhesive composition may exhibit excellent adhesion to each other.

In addition, although the adhesive composition is polymerized and cured to form an adhesive layer, the O—H group remains at the end of the acrylic acid group or the polymerized acrylic acid group, and thus the adhesive layer may exhibit excellent adhesion to the window formed of glass.

The isobornyl acrylate may be represented by the following Chemical Formula 2:

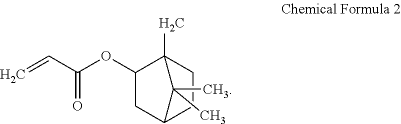

The isobornyl acrylate has a three-dimensional structure (e.g., a bulky three-dimensional structure), which causes the molecular density to be relatively low considering the space that an isobornyl acrylate molecule occupies. An adhesive layer formed of an adhesive composition that includes the isobornyl acrylate may have an excellent workability since the adhesive layer may have a low crosslink density but a high elongation index. In addition, the isobornyl acrylate having the bulky molecular structure may enhance cohesion in the adhesive layer by Van Der Waals forces. Accordingly, the adhesion of the adhesive layer may be enhanced.

The acrylic acid may be included in an amount of about 5 wt % to about 10 wt % with respect to the total weight of the adhesive composition, and the isobornyl acrylate may be included in an amount of about 5 wt % to about 10 wt % with respect to the total weight of the adhesive composition.

The adhesive composition according to the first example embodiment may further include another monomer besides the acrylic acid and the isobornyl acrylate.

The another monomer, for example, may include a monofunctional monomer and a polyfunctional monomer including two or more reactive groups.

The monofunctional monomer may include nonylphenyl carbitol acrylate, 2-hydroxy-3-phenoxypropyl acrylate, 2-ethylhexyl carbitol acrylate, 2-hydroxyethyl acrylate, N-vinylpyrrolidone, and the like.

The polyfunctional monomer may include 1,6-hexanediol di(meth)acrylate, ethylene glycol di(meth)acrylate, neopentyl glycol di(meth)acrylate, triethylene glycol di(meth)acrylate, bisphenol A bis(acryloyloxyethyl)ether, 3-pentanediol di(meth)acrylate, trimethylolpropane tri(meth)acrylate, ethoxylated trimethylolpropane tri(meth)acrylate, propoxylated trimethylolpropane tri(meth)acrylate, pentaerythritol tri(meth)acrylate, pentaerythritol tetra(meth)acrylate, dipentaerythritol penta(meth)acrylate, ethoxylated dipentaerythritol hexa(meth)acrylate, propoxylated di pentaerythritol hexa(meth)acrylate, dipentaerythritol hexa(meth)acrylate, and the like.

According to the first example embodiment and as used herein, “(meth)acrylate” may refer to either one of acrylate and methacrylate, or may refer to both of them.

The adhesive composition according to the first example embodiment may include at least one monomer selected from the group consisting of: lauryl acrylate, 2-ethoxyethyl acrylate, and 2-hydroxypropyl acrylate.

The monomer may be included in an amount of about 25 wt % to about 50 wt % with respect to the total weight of the adhesive composition. When the amount of the monomer is about 25 wt % to about 50 wt %, the adhesive composition may be readily cured by light exposure. When the amount of the monomer is less than about 25 wt %, the efficiency of photo-curing may decrease. When the amount of the monomer is more than about 50 wt %, the strength of the adhesive layer formed by curing the adhesive composition may be reduced.

The oligomer may include silicone acrylate. The silicone acrylate may be included in an amount of about 0.5 wt % to about 10 wt % with respect to the total weight of the adhesive composition.

The silicone acrylate according to the first example embodiment may be represented by the following Chemical Formula 3:

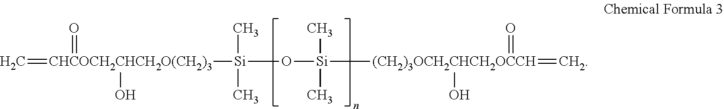

In Chemical Formula 3, n may be an integer selected from 5 to 50.

The silicone acrylate may include silicon (Si), which is a main component of glass, and may have a surface energy that is similar to glass. Accordingly, the silicone acrylate may have a high affinity for a window formed of glass. The adhesive composition according to the first example embodiment including the silicone acrylate may have excellent wettability with the window formed of glass.

FIG. 2 is a schematic view illustrating wettability. In FIG. 2, droplet 2 has a higher wettability than droplet 1. When wettability is high, the adhesive composition spreads over a relatively large area on the glass window as in droplet 2 of FIG. 2. Accordingly, the adhesive layer including the adhesive composition is highly adhesive to the window formed of glass.

In addition, the oligomer may further include at least one compound selected from urethane acrylate and polyester acrylate, each having a weight-average molecular weight (Mw) of about 5,000 to about 50,000.

When the weight-average molecular weight (Mw) of the oligomer is more than about 50,000, the affinity may decrease at the interface between the adhesive composition and its adhered surface, and the adhesive may become opaque in a high temperature and high humidity environment. When the weight-average molecular weight (Mw) of the oligomer is less than about 5,000, it may be difficult for the adhesive composition to maintain a gel state or solid state at room temperature. As used herein, “weight-average molecular weight (Mw)” refers to the average molecular weight as measured by gel permeation chromatography (GPC) based on polystyrene standards.

The urethane (meth)acrylate, for example, may be formed by reaction of a polyol compound having two or more hydroxyl groups, a compound having two or more isocyanate groups, and/or an acrylate having one or more hydroxyl groups.

Non-limiting examples of a polyol compound having two or more hydroxyl groups in the molecule may include polyether polyol, polyester polyol, caprolactone diol, bisphenol polyol, polyisoprene polyol, hydrogenated polyisoprene polyol, polybutadiene polyol, hydrogenated polybutadiene polyol, castor oil polyol, and/or polycarbonate diol, which may be used alone or as a combination of two or more thereof. As used herein, the terms “combination”, “combination thereof” and “combinations thereof” may refer to a chemical combination (e.g., an alloy or chemical compound), a mixture, or a laminated structure of components.

Non-limiting examples of a compound having two or more isocyanate groups in the molecule may include aromatic polyisocyanate, alicyclic polyisocyanate, and aliphatic polyisocyanate, which may be used alone or as a combination of two or more thereof.

Non-limiting examples of an acrylate having at least one hydroxyl group in the molecule may include mono(meth)acrylates of dihydric alcohols, such as ethylene glycol, propylene glycol, 1,3-propanediol, 1,3-butanediol, 1,4-butanediol, and polyethylene glycol; mono(meth)acrylates of trihydric alcohols, such as trimethylolethane, trimethylolpropane, and glycerin; and/or di(meth)acrylate, which may be used alone or as a combination of two or more thereof.

The oligomer may be included in an amount of about 25 wt % to about 40 wt % of the total weight of the adhesive composition. When the amount of the oligomer is about 25 wt % to about 40 wt %, the adhesive composition may be readily cured, and the adhesive layer, which is formed by curing the adhesive composition, may have suitable strength and flexibility.

The binder resin may impart viscosity to the adhesive composition. According to the first example embodiment, the type of the binder resin is not limited. Any suitable binder material commonly used in the manufacturing of the adhesive composition may be employed without limitation.

For example, the binder resin may include at least one compound selected from polybutadiene and polyisoprene, each having a weight-average molecular weight (Mw) of about 10,000 to about 100,000. The binder resin may impart flexibility to the layer formed by the adhesive composition. When the binder resin has a weight-average molecular weight (Mw) of about 10,000 to about 100,000, the adhesive composition may have stable fluidity.

The binder resin may be included in an amount of about 10 wt % to about 40 wt % of the total weight of the adhesive composition. When the amount of the binder resin is less than about 10 wt %, the permittivity and refractive index of the adhesive composition may be unnecessarily high. When the amount of the binder resin is more than about 40 wt %, the strength of the adhesive layer, which is formed by curing the adhesive composition, may decrease.

The photopolymerization initiator may absorb activation energy rays (e.g., ultraviolet rays) to generate radicals. The radicals generated by the photopolymerization initiator may react with the monomer and/or the oligomer to initiate polymerization reactions of the adhesive composition. Along with the polymerization reactions, bridging reactions may occur between the monomer, the oligomer, and the binder resin. The adhesive composition may be cured through the polymerization reaction and bridging reactions. Accordingly, an adhesive layer may be formed by curing the adhesive composition.

The photopolymerization initiator may include a first photoinitiator having a photosensitive wavelength of about 210 nm to about 290 nm and a second photoinitiator having a photosensitive wavelength of about 300 nm to about 390 nm. The first photoinitiator may also be referred to as a short wavelength photopolymerization initiator, and the second photoinitiator may also be referred to as a long wavelength photopolymerization initiator.

The first photoinitiator may absorb light having a wavelength of about 210 nm to about 290 nm, for example, about 210 nm to about 290 nm, so as to generate radicals.

The first photoinitiator may include at least one of the chemical compounds represented by the following Chemical Formulas 4 and 5:

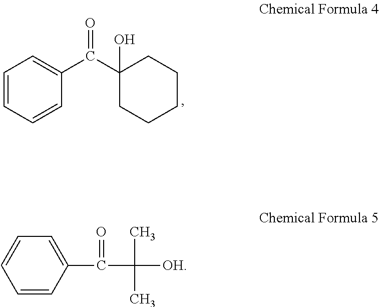

The chemical compound represented by Chemical Formula 4 is 1-hydroxycyclohexyl benzophenone, which is known as Irgacure 184™. The chemical compound represented by Chemical Formula 5 is 2-hydroxy-2-methyl-1-phenyl-propan-1-one, which is available as DAROCUR 1173™. The chemical compounds represented by the Chemical Formulas 4 and 5 may have an absorption peak at a wavelength of about 240 nm to about 260 nm.

Apart from the chemical compounds represented by Chemical Formulas 4 and 5, any other suitable photopolymerization initiator that reacts in response to a light of a wavelength of about 210 nm to about 290 nm may be used as the first photopolymerization initiator. For example, hydroxy dimethyl acetophenone (Micure HP-8™), represented by the following Chemical Formula 6, and/or hydroxy cyclohexyl phenyl ketone (CP-4™), represented by the following Chemical Formula 7, may be used as the first photopolymerization initiator:

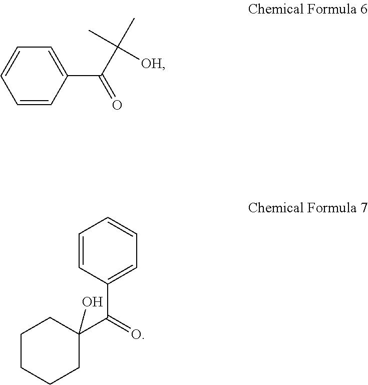

The second photoinitiator may absorb light having a wavelength of about 300 nm to about 390 nm, and in some embodiments, about 365 nm to about 385 nm, so as to generate radicals.

The second photoinitiator may include at least one selected from the chemical compounds represented by the following Chemical Formulas 8 and 9:

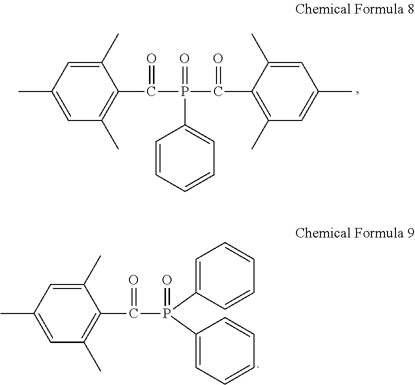

The compound represented by Chemical Formula 8 is bis(2,4,6-trimethylbenzoyl)-phenylphosphine oxide, which is available as Irgacure 819™. The compound represented by Chemical Formula 9 is 2,4,6-trimethylbenzoyl-diphenyl-phosphine oxide, which is available as DAROCUR TPO™.

Apart from the chemical compounds represented by Chemical Formulas 8 and 9, any other suitable photopolymerization initiator that reacts in response to light having a wavelength of about 300 nm to about 390 nm may be used as the second photopolymerization initiator.

Further, the adhesive composition according to the first example embodiment may further include at least one selected from an amine compound and a carboxylic acid compound as a photopolymerization auxiliary initiator.

Non-limiting examples of the amine compound may include: aliphatic amine compounds such as triethanolamine, methyl diethanolamine, and triisopropanolamine; and aromatic amine compounds such as methyl 4-dimethylamino benzoate, ethyl 4-dimethylamino benzoate, isoamyl 4-dimethylamino benzoate, 2-ethylhexyl 4-dimethylamino-benzoate, benzoic acid 2-dimethylaminoethyl, N,N-dimethyl-p-toluidine, 4,4′-bis (dimethylamino) benzophenone (i.e., Michler's ketone), and 4,4′-bis (diethylamino) benzophenone. Non-limiting examples of the carboxylic acid compound may include: aromatic heteroacetic acids such as phenylthioacetic acid, methylphenylthioacetic acid, ethyl phenylthioacetic acid, methyl ethyl phenylthioacetic acid, dimethyl phenylthio acetic acid, methoxyphenylthioacetic acid, dimethoxyphenyl thioacetic acid, chlorophenylthioacetic acid, dichlorophenylthioacetic acid, N-phenylglycine, phenoxyacetic acid, naphthylthioacetic acid, N-naphthyl glycine, and naphthoxy acetic acid.

The adhesive composition according to the first example embodiment may include a silane coupling agent as an additive. The silane coupling agent may be included in an amount of about 0.5 wt % to about 1.0 wt %.

The adhesive composition according to the first example embodiment may further include one or more additives selected from the group consisting of: filling members, polymeric compounds, dispersing members, adhesion promoters, antioxidants, ultraviolet absorbers, and flocculation inhibitors, as another additive.

Among the aforementioned additives, non-limiting examples of ultraviolet absorbers may include 2-(3-tert-butyl-2-hydroxy-5-methylphenyl)-5-chlorobenzotriazole and alkoxy benzophenone. The ultraviolet absorbers may facilitate absorption of ultraviolet (UV) light for the adhesive composition in the light-irradiation process using UV light.

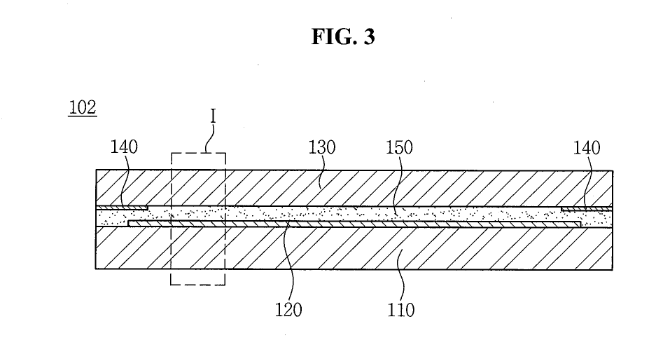

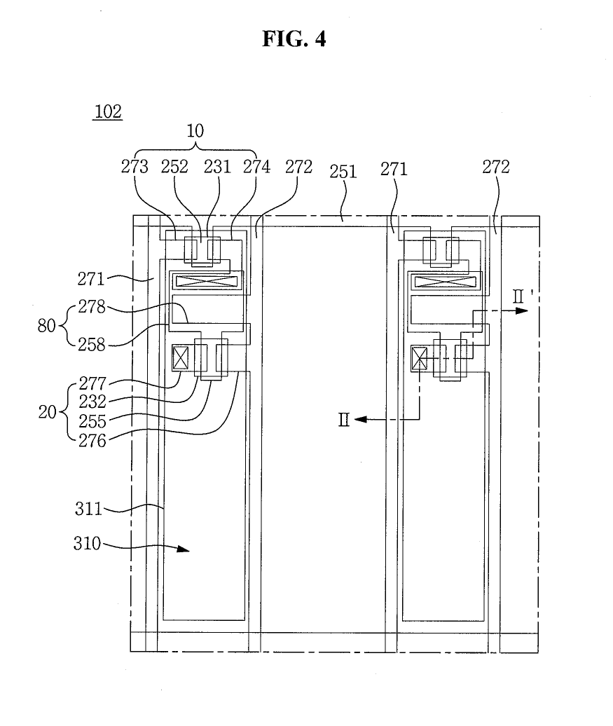

Hereinafter, a second example embodiment of the present disclosure will be described with reference to FIGS. 3, 4, and 5. In order to avoid repetition, descriptions with respect to configurations described in the foregoing will not be provided.

FIG. 3 is a cross-sectional view illustrating a display device 102 according to a second example embodiment. The display device 102 includes a display panel 110, an adhesive layer 150 on the display panel 110, and a window 130 on the adhesive layer 150.

The display panel 110 may be a liquid crystal display (“LCD”) panel or may be an organic light emitting diode (“OLED”) display panel. A polarizer 120 configured to prevent ambient light reflection may be positioned on the display panel 110. The polarizer 120 may be omitted.

The window 130 may be formed of a transparent insulating material such as glass.

A black matrix 140 may be positioned on an edge portion of the window 130. The black matrix 140 may correspond to a bezel area.

The adhesive composition of the first example embodiment may be cured, thereby forming the adhesive layer 150. The adhesive layer 150 may include an adhesive polymer resin. The adhesive layer 150 may be formed by polymerization and bridge reactions of the monomer, the oligomer, and the binder resin composing the adhesive composition. In addition, in the adhesive polymer resin, the residual monomer, oligomer, binder resin, and photopolymerization initiator, which remain unreacted, may be dispersed.

The monomer may include acrylic acid and isobornyl acrylate, the oligomer may include silicone acrylate, and the photopolymerization initiator may include a first photoinitiator having a photosensitive wavelength of about 210 nm to about 290 nm and a second photoinitiator having a photosensitive wavelength of about 300 nm to about 390 nm.

Since the adhesive composition according to the first example embodiment may include isobornyl acrylate having a three-dimensional structure, the adhesive layer 150 may have an excellent elongation index and elasticity. The adhesive layer 150 may have an elasticity of about 2.0×10⁵ Pa to about 4.0×10⁵ Pa, and an elongation index of about 200% to about 300%. Further, the adhesive layer 150 may have a glass transition temperature of about 15° C. to about 25° C.

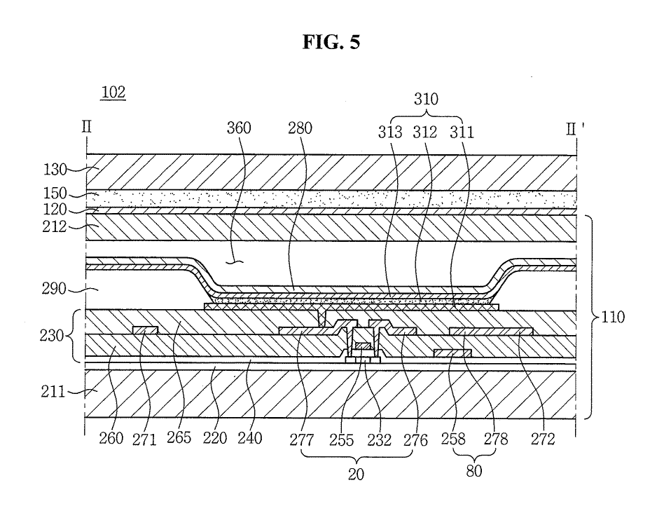

FIG. 4 is a plan view illustrating portion “I” of FIG. 3; and FIG. 5 is a cross-sectional view taken along line II-II′ of FIG. 4.

The display device 102 according to the second example embodiment is an OLED display device 102.

The OLED display device 102 according to the second example embodiment may include a substrate 211, a driving circuit 230, an OLED 310, an encapsulation substrate 212, a polarizer 120, an adhesive layer 150, and a window 130.

The substrate 211 may include an insulating substrate, which may be formed of, for example, glass, quartz, ceramic, plastic and/or the like. However, embodiments of the present disclosure are not limited thereto, and the substrate 211 may also be made of a metal, such as stainless steel and/or the like.

A buffer layer 220 is on the substrate 211. The buffer layer 220 may include one or more layers selected from a variety of inorganic layers and organic layers. However, the buffer layer 220 may not always be necessary, and may be omitted.

The driving circuit 230 is on the buffer layer 220. The driving circuit 230 may include a plurality of thin film transistors (TFTs) 10 and 20 and may drive the OLED 310. The OLED 310 may display an image by emitting light according to the driving signal applied by the driving circuit 230.

FIGS. 4 and 5 illustrate an active matrix-type organic light emitting diode display device (AMOLED display device) 102 having a 2Tr-1Cap structure. For example, the 2Tr-1Cap structure may include the two TFTs 10 and 20 and a capacitor 80 in one pixel. However, embodiments of the present disclosure are not limited thereto. In some example embodiments, the OLED display device 102 may have many different structures including three or more TFTs and two or more capacitors in one pixel, and may further include additional wirings. As used herein, the term “pixel” may refer to the smallest unit of the image display. The OLED display device 102 may display an image using a plurality of pixels.

Each pixel may include the switching TFT 10, the driving TFT 20, the capacitor 80, and the OLED 310. Herein, a structure including the switching TFT 10, the driving TFT 20, and the capacitor 80 may be referred to as the driving circuit 230. The driving circuit 230 may include a gate line 251 arranged along one direction and a data line 271 and a common power line 272 insulated from and intersecting the gate line 251. The pixel area may be defined by the gate line 251, the data line 271, and the common power line 272, but is not limited thereto. The pixel may also be defined by a black matrix or the pixel defining layer 290.

The OLED 310 may include a first electrode 311, an organic light emitting layer 312 on the first electrode 311, and a second electrode 313 on the organic light emitting layer 312. The organic light emitting layer 312 may be made of low molecular weight organic materials or high molecular weight organic materials. In the OLED 310, holes and electrons may be injected from the first electrode 311 and the second electrode 313 into the organic light emitting layer 312, respectively. The hole and the electron may combine with each other to form an exciton, and the OLED 310 may emit light energy, generated when the exciton falls (e.g., relaxes or transitions) from an excited state to a ground state.

The capacitor 80 may include a pair of capacitor plates 258 and 278 with an interlayer insulating layer 260 interposed therebetween. Herein, the interlayer insulating layer 260 may be a dielectric body. The capacitance of the capacitor 80 may be determined by the density of electric charges stored in the capacitor 80 and voltage across the pair of capacitor plates 258 and 278.

The switching TFT 10 may include a switching semiconductor layer 231, a switching gate electrode 252, a switching source electrode 273, and a switching drain electrode 274. The driving TFT 20 may include a driving semiconductor layer 232, a driving gate electrode 255, a driving source electrode 276, and a driving drain electrode 277. In addition, the semiconductor layers 231 and 232 may be insulated from the gate electrodes 252 and 255 by the gate insulating layer 240.

The switching TFT 10 may function as a switching device that selects the pixel to perform light emission. The switching gate electrode 252 may be connected to the gate line 251. The switching source electrode 273 may be connected to the data line 271. The switching drain electrode 274 may be spaced apart from the switching source electrode 273 and may be connected to one of the capacitor plates 258.

The driving TFT 20 may apply a driving power to the first electrode 311, which serves as a pixel electrode, such that the organic light emitting layer 312 of the OLED 310 in a selected pixel may emit light. The driving gate electrode 255 may be connected to the capacitor plate 258, which may be connected to the switching drain electrode 274. The driving source electrode 276 and the other capacitor plate 278 may be respectively connected to the common power line 272. The driving drain electrode 277 may be connected to the first electrode 311, which may serve as a pixel electrode of the OLED 310, through a contact hole formed on a planarization layer 265.

In the above-described structure, the switching TFT 10 may be operated by a gate voltage applied to the gate line 251, and may function to transmit a data voltage applied through the data line 271 to the driving TFT 20. A voltage equivalent to the difference between the common voltage applied by the common power line 272 to the driving TFT 20 and the data voltage transmitted from the switching TFT 10 may be stored in the capacitor 80, and current corresponding to the voltage stored in the capacitor 80 may flow to the OLED 310 through the driving TFT 20, such that the OLED 310 may emit light.

According to the second example embodiment of the present disclosure, the first electrode 311 may be formed as a reflective layer and the second electrode 313 may be formed as a transflective layer. Accordingly, light generated by the organic light emitting layer 312 may be emitted through the second electrode 313. For example, the OLED display device 102 according to the second example embodiment of the present disclosure may be a top-emission structure.

At least one layer selected from a hole injection layer (HIL) and a hole transporting layer (HTL) may be between the first electrode 311 and the organic light emitting layer 312. Further, at least one layer selected from an electron transporting layer (ETL) and an electron injection layer (EIL) may be positioned between the organic light emitting layer 312 and the second electrode 313.

The pixel defining layer 290 may have an aperture. The aperture of the pixel defining layer 290 may expose a portion of the first electrode 311. The first electrode 311, the organic light emitting layer 312, and the second electrode 313 may be sequentially laminated in the aperture of the pixel defining layer 290. Herein, the second electrode 313 may be formed not only on the organic light emitting layer 312 but also on the pixel defining layer 290. Meanwhile, the HIL, HTL, ETL, and EIL may be positioned between the pixel defining layer 290 and the second electrode 313. The OLED 310 may generate light by the organic light emitting layer 312 positioned in the aperture of the pixel defining layer 290. Accordingly, the pixel defining layer 290 may define the light emission area.

A passivation layer 280 is on the second electrode 313. The passivation layer 280 is configured to protect the OLED 310 from the external environment. The passivation layer 280 may be also referred to as a capping layer.

The encapsulation substrate 212 is on the passivation layer 280. The encapsulation substrate 212 may serve to seal the OLED 310, along with the substrate 211. In order to seal the OLED 310, a sealant may be at an edge portion between the substrate 211 and the encapsulation substrate 212.

The encapsulation substrate 212 may include an insulating substrate formed of, for example, glass, quartz, ceramic, plastic and/or the like, as in the substrate 211. The portion of the device between the substrate 211 and the encapsulation substrate 212 may be referred to as a display panel 110. Air or an inert gas may be used to fill the space 360 between the passivation layer 280 and the encapsulation substrate 212.

The polarizer 120 is on the display panel 110. The polarizer 120 is on the encapsulation substrate 212 corresponding to the display area of the display panel 110.

The adhesive layer 150 is on the display panel 110 and the polarizer 120. Since the adhesive layer 150 is described in the foregoing, its detailed description will not be repeated here.

The window 130 is on the adhesive layer 150. According to the second example embodiment, the window 130 is formed of glass. Non-limiting examples of the glass forming the window 130 may include tempered glass.

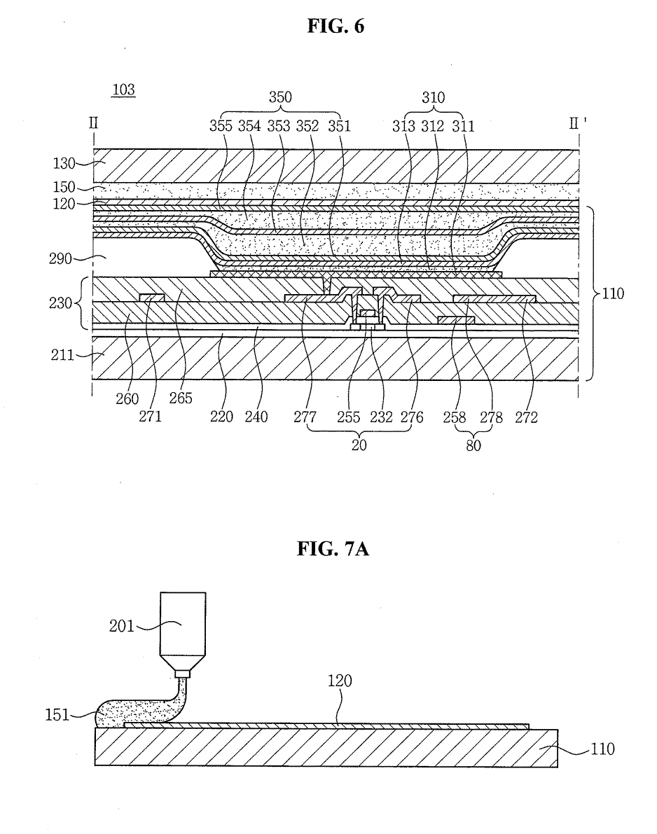

Hereinafter, a third example embodiment will be described with reference to FIG. 6. FIG. 6 is a cross-sectional view illustrating an OLED display device 103 according to a third example embodiment.

The OLED display device 103 according to the third example embodiment may include a thin film encapsulation layer 350 on an OLED 310.

The thin film encapsulation layer 350 may include one or more inorganic layers 351, 353, and 355, and one or more organic layers 352 and 354. The thin film encapsulation layer 350 may have a structure where the inorganic layers 351, 353, and 355 and the organic layers 352 and 354 are alternately laminated. In this regard, the inorganic layer 351 may be closest to the OLED 310. Although the thin film encapsulation layer 350, illustrated in FIG. 6, includes three inorganic layers 351, 353, and 355, and two organic layers 352 and 354, example embodiments of the present disclosure are not limited thereto.

The inorganic layers 351, 353, and 355 may include one or more inorganic materials selected from Al₂O₃, TiO₂, ZrO, SiO₂, AION, AIN, SiON, Si₃N₄, ZnO, and Ta₂O₅. The inorganic layers 351, 353, and 355 may be formed using methods such as chemical vapor deposition (CVD) or atomic layer deposition (ALD). However, embodiments of the present disclosure are not limited thereto, and the inorganic layers 351, 353, and 355 may be formed using one or more suitable methods available to those skilled in the art.

The organic layers 352 and 354 may include polymer-based materials. Herein, the polymer-based materials may include, for example, an acrylic resin, an epoxy resin, polyimide, and/or polyethylene. The organic layers 352 and 354 may be formed through a thermal deposition process. The thermal deposition process for forming the organic layers 352 and 354 may be performed at a range of temperatures that do not damage the OLED 310. However, embodiments of the present disclosure are not limited thereto, and the organic layers 352 and 354 may be formed using various suitable methods available to those skilled in the pertinent art.

The inorganic layers 351, 353, and 355 having a high density of thin films may prevent or efficiently reduce infiltration of, for example, moisture or oxygen. Most infiltration of moisture and oxygen into the OLED 310 may be prevented or reduced by the inorganic layers 351, 353, and 355.

Moisture and oxygen that pass through the inorganic layers 351, 353, and 355 may be further blocked by the organic layers 352 and 354. The organic layers 352 and 354 may show a relatively low efficacy at preventing or reducing moisture-infiltration compared to the inorganic layers 351, 353, and 355. However, the organic layers 352 and 354 may also serve as a buffer layer to reduce stress between the respective layers of the inorganic layers 351, 353, and 355 and the organic layers 352 and 354, in addition to preventing or reducing moisture infiltration. Further, since the organic layers 352 and 354 have planarizing properties, the uppermost surface of the thin film encapsulation layer 350 may be planarized.

The thin film encapsulation layer 350 may have a thickness of about 10 μm or less. Accordingly, the OLED display device 103 may be formed to have an overall thickness that is significantly small.

When the thin film encapsulation layer 350 is on the OLED 310, the encapsulation substrate 212 of FIG. 5 may be omitted.

The polarizer 120 is on the thin film encapsulation layer 350.

The adhesive layer 150 is on the display panel 110 and the polarizer 120.

The window 130 is on the adhesive layer 150. According to the third example embodiment, the window 130 is formed of glass.

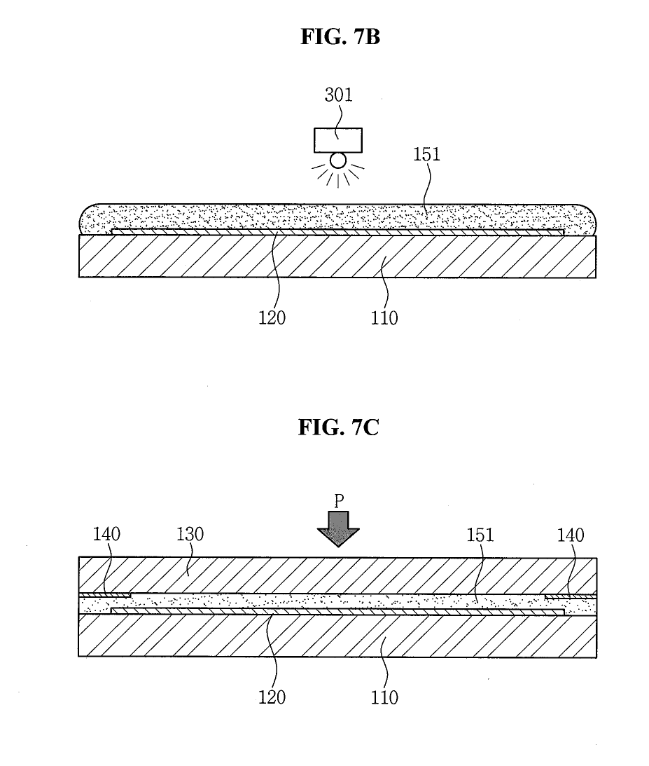

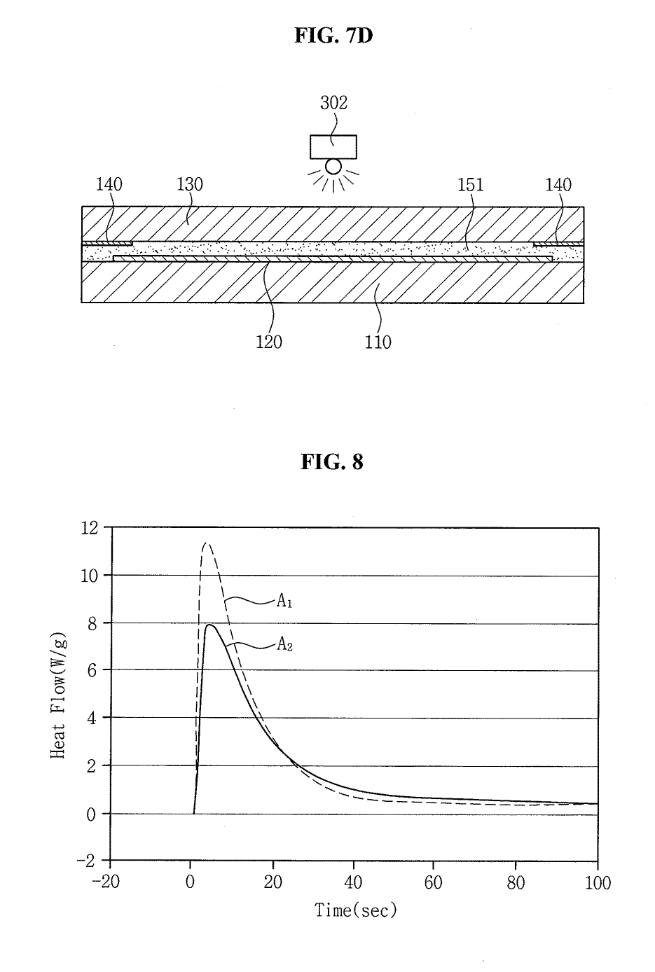

Hereinafter, a method of manufacturing the OLED display device 102 according to the second example embodiment will be described with reference to FIGS. 7A-7D.

FIGS. 7A-7D are process diagrams illustrating bonding of the display panel 110 to the window 130.

In reference to FIG. 7A, the adhesive composition 151 according to the first example embodiment is coated on a display surface of the display panel 110 on which the polarizer 120 is attached. Herein, a slit coater 201 may be used so as to coat the adhesive composition 151.

In reference to FIG. 7B, a first curing is performed on the adhesive composition 151 by a first light source 301. The first light source 301 may emit light having a center wavelength of about 365 nm to about 385 nm. For example, an LED lamp emitting ultraviolet (UV) light having a wavelength of about 365 nm to about 385 nm may be used as the first light source 301.

As such, the adhesive composition 151 may undergo the first curing under UV light having a wavelength of about 365 nm to about 385 nm (long wavelength). The first curing may also be referred to as pre-curing.

The energy of the UV light emitted from the first light source 301 may be about 500 mJ/cm² to about 1000 J/cm².

Through the first curing, a surface of the adhesive composition 151 is cured to form a coating film. Although the fluidity of the adhesive composition 151 is suppressed or reduced due to the coating film, the fluidity of the inside of the adhesive composition 151 may be maintained, and thereby workability may be enhanced.

In reference to FIG. 7C, the window 130 is positioned on the first-cured adhesive composition 151, and the window 130 is compressed toward the display panel 110. In this case, a suitable pressure (P) may be applied to the window 130, and the display panel 110 and the window 130 may adhere to each other.

In reference to FIG. 7D, the window 130 is irradiated by a second light source 302, and thus the first-cured adhesive composition 151 may be second-cured. The second curing may also be referred to as main curing.

The second light source 302 may be a metal halide lamp producing light in a relatively wide range of wavelengths.

In this case, the window 130 is irradiated with light from above, and the adhesive composition 151 is irradiated with light through the window 130. In the second curing, for example, light having an intensity (e.g., power) of about 100 mW to about 200 mW may be used.

Through the second curing, the first photoinitiator and the second photoinitiator are activated, and reactive groups of the adhesive composition 151 that were not associated (e.g., coupled) in the first curing may participate in the polymerization reaction. In the second curing process, high energy short-wavelength light is used to promote the polymerization reaction, while the long-wavelength light has excellent penetration compared to the short-wavelength light, such that the photopolymerization initiator in the adhesive composition 151 may be efficiently activated. During the second curing, an inner portion of the adhesive composition 151 may undergo curing to completely form the adhesive layer 150.

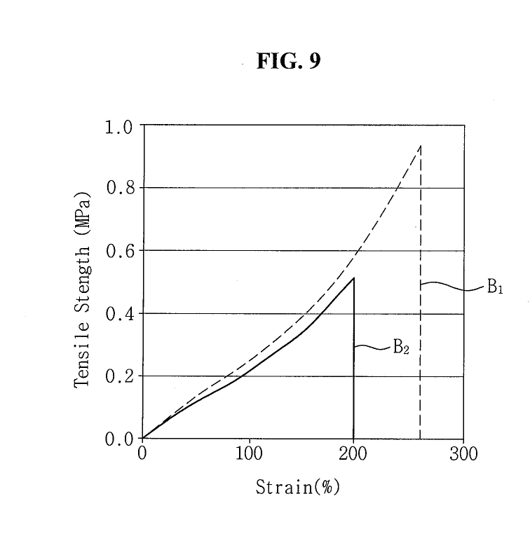

FIG. 8 is a graph illustrating heat flow in the adhesive composition versus curing time.

In order to measure the heat flow, a sample material including the adhesive composition according to the first example embodiment (example group 1) and a sample material including an adhesive composition without acrylic acid, isobornyl acrylate, silicone acrylate, and the second photoinitiator (control group 1) were used.

The variation of energy (quantity of heat) absorbed by or emitted from the sample materials was measured while the sample materials were irradiated with light. A photo-differential scanning calorimetry (Photo-DSC) Q-100 (TA instrument)™, was used as a measuring device. The illuminance of the light was about 100 mW/cm². In FIG. 8, A1 is the measured data from example group 1, and A2 is the measured data from control group 1.

The peak times of the heat flow and measured heats of reaction are shown in Table 1.

TABLE 1

| Category | Unit | Control group 1 (A2) | Example group 1 (A1) |
|---|---|---|---|
| Peak time | sec | 3.6 | 2.4 |
| Heat of reaction | J/g | 147.0 | 166.9 |

In reference to FIG. 8 and Table 1, the peak time of the heat flow appears relatively early and the heat of reaction is relatively large for the adhesive composition of example group 1, compared to the adhesive composition of control group 1. For example, the adhesive composition of example group 1 has a higher curing speed and efficiency compared to the adhesive composition of control group 1. When the curing efficiency is enhanced, the adhesion of the adhesive layer may be enhanced.

FIG. 9 is a graph illustrating the results of tensile tests on the adhesive layers.

Tensile tests were carried out on an adhesive layer formed of the adhesive composition according to the first example embodiment (sample B1) and an adhesive layer formed of an adhesive composition without acrylic acid, isobornyl acrylate, silicone acrylate, and the second photoinitiator (sample B2).

A texture analyzer (Stable Micro Systems)™, was used as a measuring device, and each of the samples B1 and B2 had a size of 30 mm (length)×10 mm (width)×2 mm (thickness). The samples B1 and B2 were elongated at a speed of about 10 mm/min in the length direction, and the tensile strength and strain ratio were measured. The strain ratio at the time of the samples 1 and 2 being fractured is the elongation index of the samples B1 and B2.

In FIG. 9, B1 is the result of a tensile test on a sample from example group 1 and B2 is the result of a tensile test on a sample from control group 1.

In reference to FIG. 9, sample B1 (example group 1) had an elongation index of about 260.5%, and the sample B2 (control group 1) had an elongation index of about 197.5%. As such, the adhesive layer formed of the adhesive composition according to the first example embodiment (sample B1) has a relatively high elongation index compared to the adhesive layer formed of the adhesive composition without acrylic acid, isobornyl acrylate, silicone acrylate, and the second photoinitiator (sample B2). An adhesive layer having a high elongation index may have a great volumetric strain ratio and excellent adhesion.

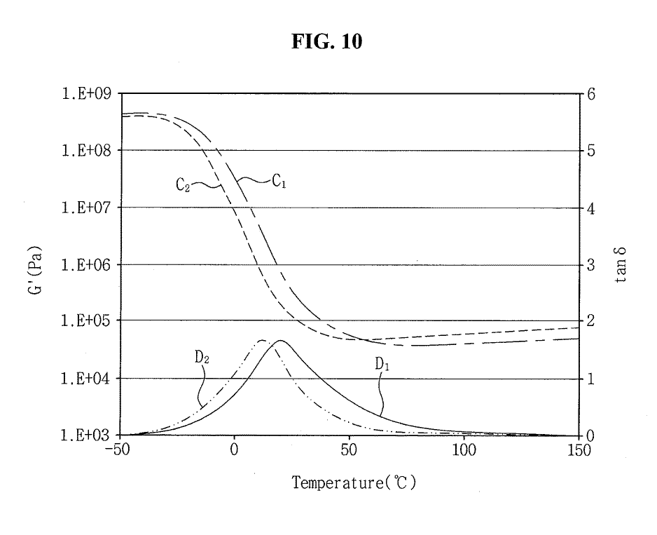

FIG. 10 is a graph illustrating the storage modulus G′ and loss tangent “tan δ” of adhesive layers versus temperature.

The elasticity of a viscoelastic material such as the adhesive layer 150 may be measured using a rheometer.

In order to compare the elasticities, the storage modulus and the loss modulus of the adhesive layer formed of the adhesive composition according to the first example embodiment (sample 1) and those of the adhesive layer formed of the adhesive composition absent acrylic acid, isobornyl acrylate, silicone acrylate, and the second photoinitiator (sample 2) were measured.

An ARES-G2 (Rheometer)™ and 8 mm Al disposable plates were used (at a frequency of about 10 Hz and a strain of about 0.5%) to measure the storage moduli and the loss moduli of samples 1 and 2 by increasing the temperature from about −150° C. to about 200° C. at a heating rate of about 5° C./min.

In FIG. 10, G′ represents the storage modulus. The storage modulus G′ corresponds to the elasticity of the viscoelastic samples 1 and 2. In FIG. 10, C1 is the storage modulus measurement of sample 1 (example group 1) and C2 is the storage modulus measurement of sample 2 (control group 1).

In reference to FIG. 10, sample 1 (C1, example group 1) has an elasticity of about 3.6×10⁵ Pa and sample 2 (C2, control group 1) has an elasticity of about 1.2×10⁵ Pa.

In addition, in FIG. 10, “tan δ” represents the loss tangent. The “tan δ” is calculated as the ratio of the storage modulus to the loss modulus. That is, when the loss modulus is denoted as G″ and the storage modulus is denoted as G′, tan δ is obtained by the following Formula 1:

tan δ=G′/G″. Formula 1

In this regard, the peak in the graph of loss tangent (tan δ) versus temperature corresponds to the glass transition temperature (Tg).

In FIG. 10, D1 is the tan δ measurement of sample 1 (example group 1) and D2 is the tan δ measurement of sample 2 (control group 1). In reference to FIG. 10, the sample 1 (D1, example group 1) has a glass transition temperature (Tg) of about 18.7° C. and the sample 2 (D2, control group 1) has a glass transition temperature (Tg) of about 12° C.

As set forth hereinabove, the adhesive composition according to the example embodiment may include acrylic acid and isobornyl acrylate as a monomer, silicone acrylate as an oligomer, and a short-wavelength initiator and a long-wavelength initiator as photopolymerization initiators, and may have excellent adhesion with respect to a glass window.

As used herein, expressions such as “at least one of” and “one of”, when preceding a list of elements, modify the entire list of elements and do not modify the individual elements of the list. Further, the use of “may” when describing embodiments of the present disclosure refers to “one or more embodiments of the present disclosure”.

In addition, as used herein, the terms “use”, “using”, and “used” may be considered synonymous with the terms “utilize”, “utilizing”, and “utilized”, respectively.

As used herein, the terms “substantially”, “about”, and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present disclosure. Various features of the above described and other embodiments can be mixed and matched in any manner, to produce further embodiments consistent with the disclosure.

While this disclosure has been described in connection with what is presently considered to be practical example embodiments, it is to be understood that the disclosure is not limited to the disclosed embodiments but, on the contrary, is intended to cover various modifications and equivalent arrangements included within the spirit and scope of the appended claims and equivalents thereof.

What is claimed is:

1. An adhesive composition comprising:
a monomer in an amount of about 25 wt % to about 50 wt %;
an oligomer in an amount of about 25 wt % to about 40 wt %;
a binder resin in an amount of about 10 wt % to about 40 wt %; and
a photopolymerization initiator in an amount of about 1 wt % to about 10 wt % with respect to the total weight of the adhesive composition,
wherein the monomer comprises acrylic acid and isobornyl acrylate,
the oligomer comprises silicone acrylate, and
the photopolymerization initiator comprises a first photoinitiator having a photosensitive wavelength of about 210 nm to about 290 nm and a second photoinitiator having a photosensitive wavelength of about 300 nm to about 390 nm.

2. The adhesive composition of claim 1, wherein the acrylic acid is present in an amount of about 5 wt % to about 10 wt % with respect to the total weight of the adhesive composition.

3. The adhesive composition of claim 1, wherein the isobornyl acrylate is present in an amount of about 5 wt % to about 10 wt % with respect to the total weight of the adhesive composition.

4. The adhesive composition of claim 1, wherein the silicone acrylate is present in an amount of about 0.5 wt % to about 10 wt % with respect to the total weight of the adhesive composition.

5. The adhesive composition of claim 1, wherein the silicone acrylate is represented by the following Chemical Formula 3: 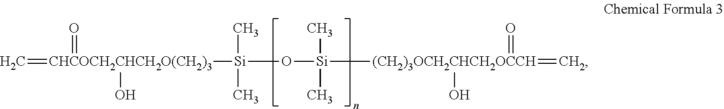
wherein n is an integer selected from 5 to 50.

6. The adhesive composition of claim 1, wherein the first photoinitiator comprises at least one selected from chemical compounds represented by the following Chemical Formulas 4 and 5:

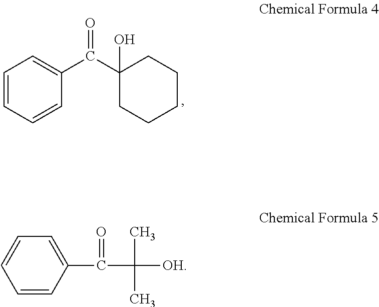

7. The adhesive composition of claim 1, wherein the second photoinitiator comprises at least one selected from chemical compounds represented by the following Chemical Formulas 8 and 9:

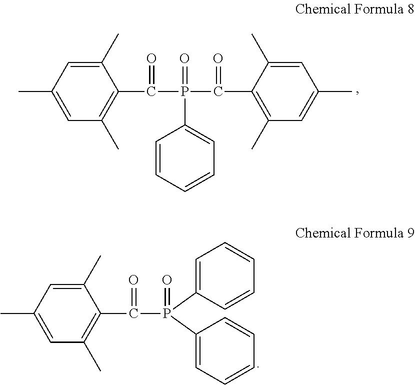

8. The adhesive composition of claim 1, wherein the monomer further comprises at least one selected from lauryl acrylate, 2-ethoxyethyl acrylate, and 2-hydroxypropyl acrylate.

9. The adhesive composition of claim 1, wherein the oligomer further comprises at least one selected from urethane acrylate and polyester acrylate, each having a weight-average molecular weight (Mw) of about 5,000 to about 50,000.

10. A method of manufacturing a display device, the method comprising:
coating an adhesive composition on a display surface of a display panel;
performing a first curing on the adhesive composition using a first light source;
disposing a window on the first-cured adhesive composition
performing a second curing on the first-cured adhesive composition by irradiating the window using a second light source,
wherein the adhesive composition comprises:
a monomer in an amount of about 25 wt % to about 50 wt %;
an oligomer in an amount of about 25 wt % to about 40 wt %;
a binder resin in an amount of about 10 wt % to about 40 wt %; and
a photopolymerization initiator in an amount of about 1 wt % to about 10 wt % with respect to the total weight of the adhesive composition,
the monomer comprises acrylic acid and isobornyl acrylate,
the oligomer comprises silicone acrylate,
the photopolymerization initiator comprises a first photoinitiator having a photosensitive wavelength of about 210 nm to about 290 nm and a second photoinitiator having a photosensitive wavelength of about 300 nm to about 390 nm, and
the second light source emits light having a wavelength longer than a wavelength of the first light source.

11. The method of claim 10, wherein the acrylic acid is present in an amount of about 5 wt % to about 10 wt % with respect to the total weight of the adhesive composition.

12. The method of claim 10, wherein the isobornyl acrylate is present in an amount of about 5 wt % to about 10 wt % with respect to the total weight of the adhesive composition.

13. The method of claim 10, wherein the silicone acrylate is present in an amount of about 0.5 wt % to about 10 wt % with respect to the total weight of the adhesive composition.

14. The method of claim 10, wherein the first light source emits light having a center wavelength of about 365 nm to about 385 nm.

15. The method of claim 10, wherein the second light source is a metal halide lamp.

16. The method of claim 10, wherein the display panel is one selected from a liquid crystal display panel and an organic light emitting diode display panel.

17. A display device comprising:
a display panel;
an adhesive layer on the display panel; and
a window on the adhesive layer,
wherein the adhesive layer comprises a monomer, an oligomer, a binder resin, and a photopolymerization initiator,
the monomer comprises acrylic acid and isobornyl acrylate,
the oligomer comprises silicone acrylate, and
the photopolymerization initiator comprises a first photoinitiator having a photosensitive wavelength of about 210 nm to about 290 nm and a second photoinitiator having a photosensitive wavelength of about 300 nm to about 390 nm.

18. The display device of claim 17, wherein the adhesive layer has:
an elasticity of about 2.0×10⁵ Pa to about 4.0×10⁵ Pa;
an elongation index of about 200% to about 300%; and
a glass transition temperature of about 15° C. to about 25° C.

19. The display device of claim 17, wherein the display panel is one selected from a liquid crystal display panel and an organic light emitting diode display panel.
